(19) United States
(12) Patent Application Publication
(10) Pub. No.: US 2013/0009660 A1
(43) Pub. Date: Jan. 10, 2013

(54) ELECTRICAL CONNECTING DEVICE

(75) Inventors: Chiang-Cheng FAN, Taoyuan Hsien (TW); Mao-Sheng LIU, Taoyuan Hsien (TW); Li-Shou CHEN, Taoyuan Hsien (TW); Hsi-Ping TSAI, Taoyuan Hsien (TW); Han-Jen TSENG, Taoyuan Hsien (TW)

(73) Assignee: CHROMA ATE INC., Taoyuan Hsien (TW)

(21) Appl. No.: 13/543,409

(22) Filed: Jul. 6, 2012

(30) Foreign Application Priority Data
Jul. 8, 2011 (TW) 100124341

(51) Int. Cl. G01R 31/00

(52) U.S. Cl. 324/756.05

(57) ABSTRACT

An electrical connecting device is provided. The electrical connecting device comprises at least one jig for electrically connecting and clamping at least one electrode of at least one electrical component. The jig comprises a first clamping portion, a second clamping portion and a first detecting elastic sheet. The second clamping portion is disposed opposite to the first clamping portion. The electrode is adapted to be electrically connected to and clamped between the first clamping portion and the second clamping portion. The first detecting elastic sheet is fixed with the first clamping portion. The first detecting elastic sheet is connected to a first sensor and formed with a first contact portion. The first sensor is used for sensing a first parameter of the electrical component and the first contact portion is used for contacting the electrode.

### BACKGROUND OF THE INVENTION

1. Field of the Invention

The present invention relates to a jig, and more particularly, to a jig of an electrical connecting device.

2. Description of the Related Art

With the advent of the information age, various electrical components have become widely used in daily life and different industries. Before being used, electrical components need to undergo various processes and pass various tests. Therefore, an electrical connecting device used in the tests and processes that electrical components need to undergo is a tool which has to be frequently used before the electrical components themselves can be used.

When a general electrical component undergoes the various processes, an electrical connecting device is required to connect the electrodes of the electrical component to a process apparatus, and sensing terminals are used for contacting the electrodes to sense a parameter(s) of the electrical component to be used as reference data for process control or Quality Control (QC) of the electrical component.

However, since the electrical connecting device is used for connecting the electrodes to the process apparatus, and the sensing terminals are used for contacting the electrodes, the action of electrically connecting the electrodes needs to be performed twice, greatly increasing the operation time and costs of such process and lowering the stability of the sensing terminals contacting the electrodes.

In view of this, the question of how best to enable the electrical connecting device to electrically connect an electrical device to another apparatus stably and meanwhile enable the sensing terminals to contact the electrodes of the electrical component stably to sense the parameters of the electrical component is an urgent problem to be solved in the industry.

### SUMMARY OF THE INVENTION

One objective of the present invention is to provide an electrical connecting device capable of electrically connecting an electrical device to another apparatus stably and meanwhile enable a sensing terminal to contact an electrode of an electrical component stably to sense a parameter of the electrical component.

To achieve the above objective, -the electrical connecting device of the present invention used for electrically connecting and clamping at least one electrode of at least one electrical component includes at least one jig. The jig includes a first clamping portion, a second clamping portion and a first detecting elastic sheet. The second clamping portion is disposed opposite to the first clamping portion. The electrode is adapted to be electrically connected to and clamped between the first clamping portion and the second clamping portion. The first detecting elastic sheet is fixed with the first clamping portion. The first detecting elastic sheet is connected to a first sensor and formed with a first contact portion. The first sensor is used for sensing a first parameter of the electrical component and the first contact portion is used for contacting the electrode.

Therefore, the electrical connecting device of the present invention can electrically connect the electrical device to another apparatus and meanwhile use the detecting elastic sheet integrated in the electrical connecting device to contact the electrode of the electrical component stably to sense the parameter of the electrical component.

### BRIEF DESCRIPTION OF THE DRAWINGS

The invention will be described according to the appended drawings in which:

FIG. 1 is a schematic perspective view of an electrical connecting device in accordance with a preferred embodiment of the present invention;

FIG. 2 is a schematic top view of the electrical connecting device in accordance with a preferred embodiment of the present invention;

FIG. 3 is a schematic perspective exploded view of a first jig of the electrical connecting device in accordance with a preferred embodiment of the present invention; and

FIG. 4 is a schematic perspective exploded view of a second jig of the electrical connecting device in accordance with a preferred embodiment of the present invention.

### PREFERRED EMBODIMENT OF THE PRESENT INVENTION

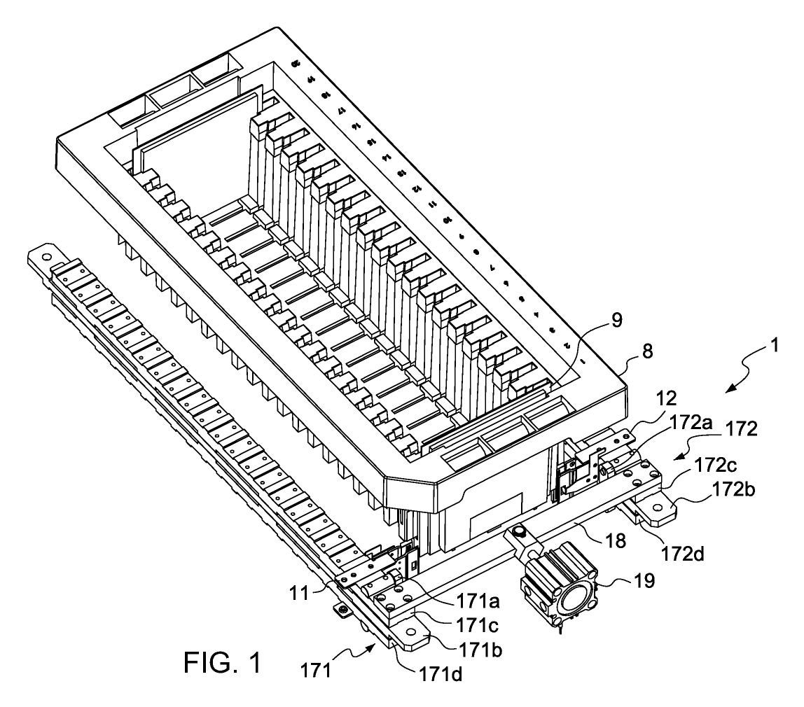

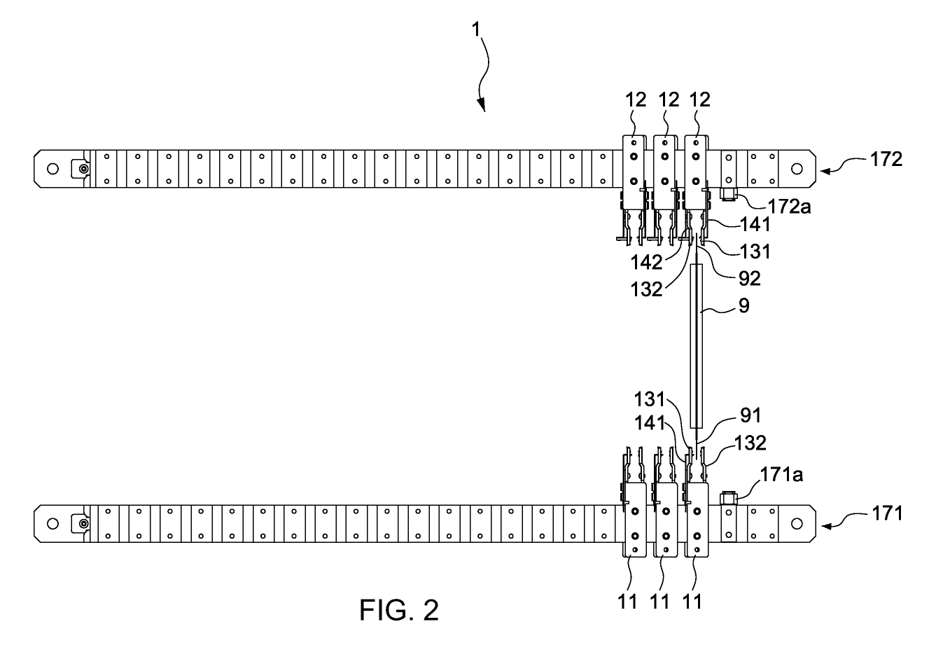

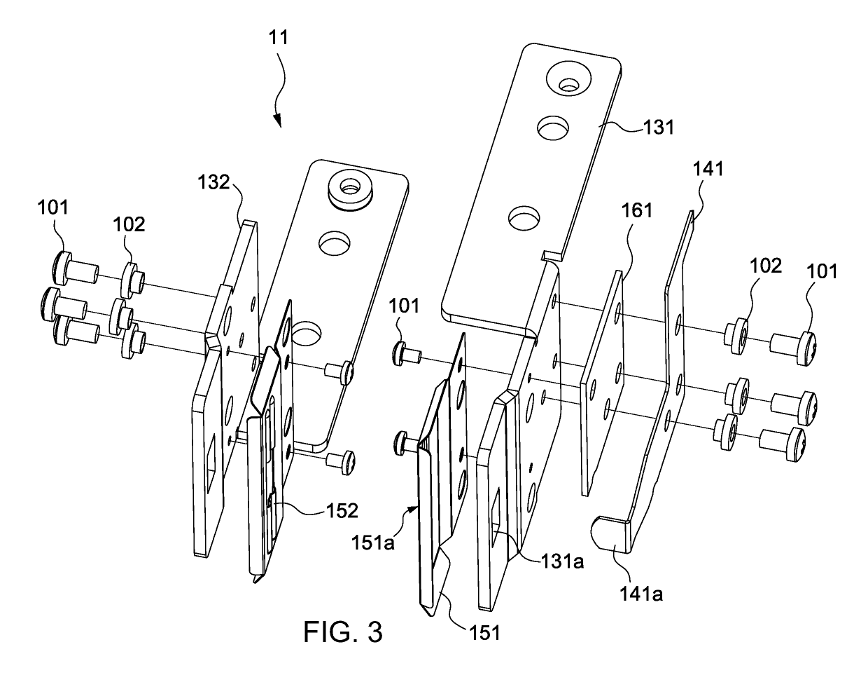

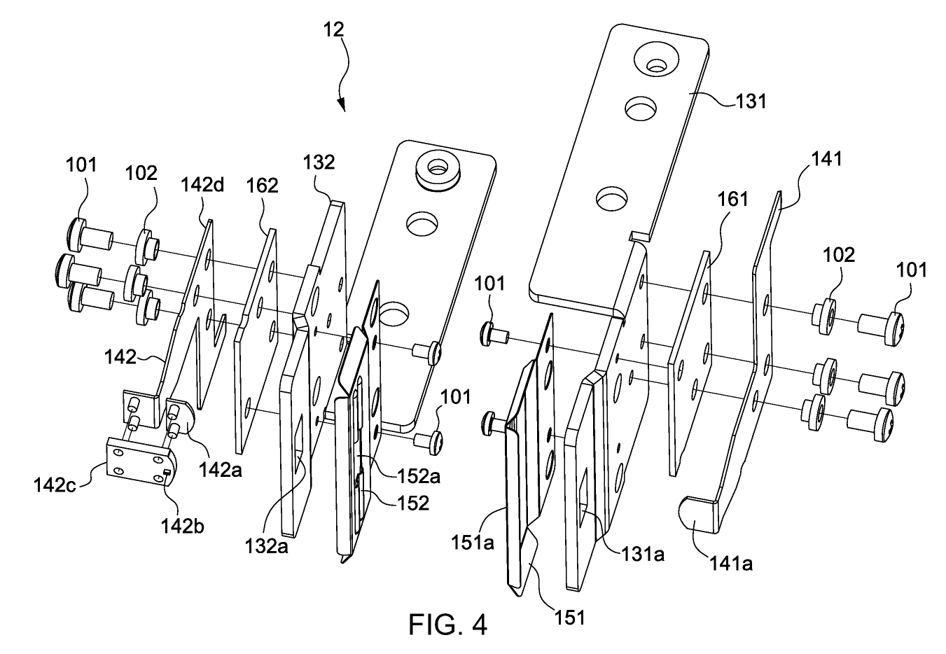

For a preferred embodiment of an electrical connecting device 1 in the present invention, reference is made to FIG. 1 and FIG. 2 first. The electrical connecting device 1 of the present invention includes at least one jig 11, 12. The jig 11, 12 is used for electrically connecting and clamping at least one electrode 91, 92 of at least one electrical component 9. Each jig includes a first clamping portion 131, a second clamping portion 132 and a first detecting elastic sheet 141. The second clamping portion 132 is disposed opposite to the first clamping portion 131. The electrode 91, 92 is adapted to be electrically connected to and clamped between the first clamping portion 131 and the second clamping portion 132. Referring to FIG. 3 and FIG. 4 further, the first detecting elastic sheet 141 is fixed with the first clamping portion 131. The first detecting elastic sheet 141 is connected to a first sensor (not shown) and formed with a first contact portion 141a. The first sensor is used for sensing a first parameter of the electrical component 9, and the first contact portion 141a is used for contacting the electrode 91, 92 stably by using the elasticity of the first detecting elastic sheet 141. The electrical connecting device 1 in the preferred embodiment of the present invention electrically connects and clamps multiple electrodes 91, 92 of a plurality of the electrical components 9 at the same time, and thus includes a plurality of jigs 11, 12.

The jigs 11, 12 are divided into at least one first jig 11 (shown in FIG. 3), which does not include a second detecting elastic sheet 142, and at least one second jig 12 (shown in FIG. 4), which includes the second detecting elastic sheet 142. The first jig 11 is used for electrically connecting and clamping a first electrode 91 of the electrical component 9, and the second jig 12 is used for electrically connecting and clamping a second electrode 92 of the electrical component 9.

Referring to FIG. 3, in the first jig 11, the first detecting elastic sheet 141 is fixed to an outside part of the first clamping portion 131. The first clamping portion 131 includes a first perforation 131a. The first contact portion 141a passes through the first perforation 131a and is partially disposed between the first clamping portion 131 and the second clamping portion 132 so as to contact the first electrode 91 of the electrical component 9.

Preferably, the first jig 11 further includes a first contact elastic sheet 151 and a second contact elastic sheet 152. The first contact elastic sheet 151 is disposed between the first clamping portion 131 and the second clamping portion 132 and is fixed with the first clamping portion 131. The second contact elastic sheet 152 is disposed, opposite to the first contact elastic sheet 151, between the first clamping portion 131 and the second clamping portion 132 and is fixed with the second clamping portion 132. Therefore, the first clamping portion 131 and the second clamping portion 132 electrically connect and clamp the first electrode 91 of the electrical component 9 stably through the elasticity of the first contact elastic sheet 151 and the second contact elastic sheet 152 respectively.

In the first jig 11, the first contact elastic sheet 151 has a first through hole 151a. The first contact portion 141a of the first detecting elastic sheet 141 passes through the first through hole 151a and is partially disposed between the first clamping portion 131 and the second clamping portion 132 so as to contact the first electrode 91 of the electrical component 9.

Preferably, the first jig 11 of the present invention further includes a first insulation sheet 161 clamped between the first clamping portion 131 and the first detecting elastic sheet 141 to insulate the first clamping portion 131 from the first detecting elastic sheet 141. Therefore, various electrical signals or electrical energy transmitted to the first electrode 91 of the electrical component 9 through the electrical connection of the first clamping portion 131 and the second clamping portion 132 can be isolated from the first parameter detected by the first detecting elastic sheet 141, so as to avoid interference.

Moreover, in the first jig 11 of the present invention, a plurality of screws 101 and insulating plastic washers 102 are used to fix the first contact elastic sheet 151, the first clamping portion 131, the first insulation sheet 161 and the first detecting elastic sheet 141 with each other, and fix the second contact elastic sheet 152 and the second clamping portion 132 with each other.

Referring to FIG. 4, in addition to the first clamping portion 131, the second clamping portion 132 and the first detecting elastic sheet 141, the second jig 12 further includes a second detecting elastic sheet 142. The second detecting elastic sheet 142 is fixed with the second clamping portion 132 of the second jig 12. The second detecting elastic sheet 142 is formed with a second contact portion 142a and includes a second sensor 142b. The second sensor 142b is used for sensing a second parameter of the electrical component 9, and the second contact portion 142a is used for contacting the second electrode 92 stably by using the elasticity of the second detecting elastic sheet 142. Therefore, the electrical connecting device 1 of the present invention can detect the two different parameters of the electrical component 9 while performing a process on the electrical component 9.

In a preferred embodiment, the first sensor connected by the first detecting elastic sheet 141 is a voltage sensor, and the second sensor 142b disposed in the second detecting elastic sheet 142 is a temperature sensor. The second sensor 142b may be a thermistor. Referring to FIG. 3 and FIG. 4, in the electrical connecting device 1 of the present invention, the first detecting elastic sheet 141 of the first jig 11 and the first detecting elastic sheet 141 of the second jig 12 are used for respectively contacting and electrically connecting the first electrode 91 and the second electrode 92 of the electrical component 9 to the first sensor of a voltage sensing apparatus to detect a voltage difference between the first electrode 91 and the second electrode 92 of the electrical component 9. In another aspect, in the electrical connecting device 1 of the present invention, the second detecting elastic sheet 142 is used for contacting the second electrode 92 of the electrical component 9, and the second sensor 142b is used for sensing the temperature of the electrical component 9 through the second contact portion 142a of the second detecting elastic sheet 142.

Referring to FIG. 4 in particular, in the above preferred embodiment, the second detecting elastic sheet 142 of the second jig 12 further includes a circuit board 142c and an elastic sheet body 142d. The circuit board 142c is fixed with the second contact portion 142a and the elastic sheet body 142d respectively. The second sensor 142b is disposed on the circuit board 142c and electrically connected to the elastic sheet body 142d through the circuit board 142c.

The second jig 12 is similar to the first jig 11 in the aspects of the first clamping portion 131 and the first detecting elastic sheet 141. In the second jig 12, the first detecting elastic sheet 141 is fixed to an outside part of the first clamping portion 131. The first clamping portion 131 includes a first perforation 131a. The first contact portion 141a of the first detecting elastic sheet 141 passes through the first perforation 131a and is partially disposed between the first clamping portion 131 and the second clamping portion 132 so as to contact the second electrode 92 of the electrical component 9. The second detecting elastic sheet 142 is fixed to an outside part of the second clamping portion 132. The second clamping portion 132 also includes a second perforation 132a. The second contact portion 142a of the second detecting elastic sheet 142 passes through the second perforation 132a and is partially disposed between the first clamping portion 131 and the second clamping portion 132 so as to contact the second electrode 92 of the electrical component 9.

Preferably, like the first jig 11, the second jig 12 further includes a first contact elastic sheet 151 and a second contact elastic sheet 152. The first contact elastic sheet 151 is disposed between the first clamping portion 131 and the second clamping portion 132 and is fixed with the first clamping portion 131. The second contact elastic sheet 152 is disposed, opposite to the first contact elastic sheet 151, between the first clamping portion 131 and the second clamping portion 132 and is fixed with the second clamping portion 132. The first clamping portion 131 and the second clamping portion 132 electrically connect and clamp the second electrode 92 of the electrical component 9 stably through the elasticity of the first contact elastic sheet 151 and the second contact elastic sheet 152 respectively.

In the second jig 12, the first contact elastic sheet 151 has a first through hole 151a. The first contact portion 141a of the first detecting elastic sheet 141 passes through the first through hole 151a and is partially disposed between the first clamping portion 131 and the second clamping portion 132 so as to contact the second electrode 92 of the electrical component 9. The second contact elastic sheet 152 also has a second through hole 152a. The second contact portion 142a of the second detecting elastic sheet 142 passes through the second through hole 152a and is partially disposed between the first clamping portion 131 and the second clamping portion 132 so as to contact the second electrode 92 of the electrical component 9.

Preferably, the second jig 12 includes a first insulation sheet 161 and a second insulation sheet 162. The first insulation sheet 161 is clamped between the first clamping portion 131 and the first detecting elastic sheet 141 to insulate the first clamping portion 131 from the first detecting elastic sheet 141. The second insulation sheet 162 is clamped between the second clamping portion 132 and the second detecting elastic sheet 142 to insulate the second clamping portion 132 from the second detecting elastic sheet 142. Therefore, various electrical signals or electrical energy transmitted to the second electrode 92 of the electrical component 9 through the electrical connection of the first clamping portion 131 and the second clamping portion 132 can be isolated from the first parameter (for example, the voltage) detected by the first detecting elastic sheet 141 and the second parameter (for example, the temperature) detected by the second detecting elastic sheet 142, so as to avoid interference. Moreover, in the second jig 12 of the present invention, a plurality of screws 101 and insulating plastic washers 102 are used to fix the first contact elastic sheet 151, the first clamping portion 131, the first insulation sheet 161 and the first detecting elastic sheet 141 with each other, and fix the second contact elastic sheet 152, the second clamping portion 132, the second insulation sheet 162 and the second detecting elastic sheet 142 with each other.

Referring to FIG. 1 and FIG. 2, in order to simultaneously actuate the first jig 11 and the second jig 12 so that the first clamping portions 131 and the second clamping portions 132 of the first jig 11 and the second jig 12 simultaneously clamp the first electrode 91 and the second electrode 92 of the electrical component 9 respectively, the electrical connecting device 1 of the present invention further includes a first relative sliding device 171, a second relative sliding device 172 and a connecting rod 18.

The first relative sliding device 171 includes a link 171a, a fixed portion 171b, a first sliding portion 171c and a second sliding portion 171d. The first sliding portion 171c of the first relative sliding device 171 is fixed with the first clamping portion 131 of the first jig 11, and the second sliding portion 171d of the first relative sliding device 171 is fixed with the second clamping portion 132 of the first jig 11. A first end of the link 171a is pivotally fixed with the first sliding portion 171c, a second end of the link 171a is pivotally fixed with the second sliding portion 171d, and a center of the link 171a is pivotally fixed with the fixed portion 171b.

Similarly, the second relative sliding device 172 also includes a link 172a, a fixed portion 172b, a first sliding portion 172c and a second sliding portion 172d. The first sliding portion 172c of the second relative sliding device 172 is fixed with the first clamping portion 131 of the second jig 12, and the second sliding portion 172d of the second relative sliding device 172 is fixed with the second clamping portion 132 of the second jig 12. A first end of the link 172a is pivotally fixed with the first sliding portion 172c, a second end of the link 172a is pivotally fixed with the second sliding portion 172d, and a center of the link 172a is pivotally fixed with the fixed portion 172b.

The connecting rod 18 is fixed with the first sliding portion 171a of the first relative sliding device 171 and the first sliding portion 172a of the second relative sliding device 172. Therefore, when the connecting rod 18 is pushed by an external force, the first clamping portion 131 and the second clamping portion 132 of the first jig 11 move in opposite directions and the first clamping portion 131 and the second clamping portion 132 of the second jig 12 move in opposite directions. The electrical connecting device 1 of the present invention may further include a pneumatic cylinder 19 fixed with the connecting rod 18 so as to provide the external force.

Referring to FIG. 1 and FIG. 2, the electrical connecting device 1 of the present invention may preferably be used for connecting a plurality of the electrical components 9 at the same time. The electrical components 9 may preferably be placed on a tray 8. Therefore, the electrical connecting device 1 of the present invention may include a plurality of the first jigs 11 and a plurality of the second jigs 12 accordingly, where the number of the first jigs 11 and the number of the second jigs 12 correspond to the number of the electrical components 9. The first jigs 11 are used for electrically connecting and clamping all the first electrodes 91 of all the electrical components 9 respectively, and the second jigs 12 are used for electrically connecting and clamping all the second electrodes 92 of all the electrical components 9 respectively. In FIG. 1 and FIG. 2, only a part of the first jigs 11 and a part of the second jigs 12 are shown as an example. Persons of ordinary skill in the art can derive that, if the number of the first jigs 11 and the second jigs 12 is increased, the electrical connecting device 1 of the present invention can electrically connect and clamp all first electrodes 91 and all second electrodes 92 of more electrical components 9 simultaneously.

In order to simultaneously actuate all of the first jigs 11 and the second jigs 12 so that all of the first clamping portions 131 and the second clamping portions 132 of the first jigs 11 and the second jigs 12 are simultaneously actuated and clamp the first electrodes 91 and the second electrodes 92 of all the electrical components 9, all the first jigs 11 are mounted on the first relative sliding device 171 and all the second jigs 12 are mounted on the second relative sliding device 172.

The first sliding portion 171c of the first relative sliding device 171 is fixed with the first clamping portions 131 of all the first jigs 11, and the second sliding portion 171d of the first relative sliding device 171 is fixed with the second clamping portions 132 of all the first jigs 11. The first sliding portion 172c of the second relative sliding device 172 is fixed with the first clamping portions 131 of all the second jigs 12, and the second sliding portion 172d of the second relative sliding device 172 is fixed with the second clamping portions 132 of all the second jigs 12. Therefore, when the connecting rod 18 is pushed by an external force, the first clamping portions 131 and the second clamping portions 132 of all the first jigs 11 move in opposite directions and the first clamping portions 131 and the second clamping portions 132 of all the second jigs 12 move in opposite directions.

In a preferred embodiment, the second detecting elastic sheet 142 of the second jig 12 is used for detecting the temperature of the electrical component 9, so the second electrode 92 clamped by the second jig 12 is preferably made of a material with better thermal conductivity. Therefore, if a cathode of the electrical component 9 is made of a material with better thermal conductivity than an anode, the first electrode 91 of the electrical component 9 is preferably an anode, and the second electrode 92 of the electrical component 9 is preferably a cathode.

In an application of the electrical connecting device 1 of the present invention, the electrical component 9 clamped and electrically connected by the electrical connecting device 1 is a pouch-type battery. In this application, in the electrical connecting device 1 of the present invention, the first clamping portion 131 and the second clamping portion 132 of the first jig 11 may be used to clamp the first electrode 91 of the pouch-type battery, and the first clamping portion 131 and the second clamping portion 132 of the second jig 12 may be used to clamp the second electrode 92 of the pouch-type battery, so as to perform a process such as charging or formation on the pouch-type battery. At the same time, in the electrical connecting device 1 of the present invention, the first detecting elastic sheet 141 of the first jig 11 and the first detecting elastic sheet 141 of the second jig 12 may be used for respectively contacting and electrically connecting the first electrode 91 and the second electrode 92 of the pouch-type battery to the first sensor of the voltage sensing apparatus to detect a voltage difference between the first electrode 91 and the second electrode 92 of the pouch-type battery, the second detecting elastic sheet 142 may be used for contacting the second electrode 92 of the pouch-type battery, and the second sensor 142b may be used for sensing the temperature of the pouch-type battery through the second contact portion 142a of the second detecting elastic sheet 142. Therefore, the condition of the pouch-type battery during the process such as charging or formation can be well known and controlled accordingly.

Therefore, the electrical connecting device of the present invention can electrically connect the electrical device to another apparatus and meanwhile use the detecting elastic sheets integrated in the electrical connecting device to contact the electrodes of the electrical component stably to sense the parameter(s) of the electrical component. The above embodiment only exemplifies a preferred embodiment -of the present invention and is not intended to limit the present invention. Other embodiments -can be easily derived by persons of ordinary skill in the art with reference to the above embodiment. The scope of this application should be determined on the basis of the appended claims.

What is claimed is:

1. An electrical connecting device, comprising at least one jig for electrically connecting and clamping at least one electrode of at least one electrical component, wherein the jig comprises:
a first clamping portion;
a second clamping portion, disposed opposite to the first clamping portion, wherein the electrode is adapted to be electrically connected to and clamped between the first clamping portion and the second clamping portion; and
a first detecting elastic sheet, fixed with the first clamping portion, wherein the first detecting elastic sheet is connected to a first sensor and formed with a first contact portion, the first sensor is used for sensing a first parameter of the electrical component, and the first contact portion is used for contacting the electrode.

2. The electrical connecting device according to claim 1, wherein the electrical connecting device comprises a plurality of jigs, the jigs are divided into at least one first jig and at least one second jig, the first jig is used for electrically connecting and clamping a first electrode of the electrical component, and the second jig is used for electrically connecting and clamping a second electrode of the electrical component.

3. The electrical connecting device according to claim 2, wherein the second jig further comprises:
a second detecting elastic sheet, fixed with the second clamping portion of the second jig, wherein the second detecting elastic sheet comprises a second sensor and is formed with a second contact portion, the second sensor is used for sensing a second parameter of the electrical component, and the second contact portion is used for contacting the electrode.

4. The electrical connecting device according to claim 3, wherein the second detecting elastic sheet further comprises a circuit board and an elastic sheet body, the circuit board is fixed with the second contact portion and the elastic sheet body respectively, and the second sensor is disposed on the circuit board and electrically connected to the elastic sheet body through the circuit board.

5. The electrical connecting device according to claim 3, wherein in the first jig:
the first detecting elastic sheet is fixed to an outside part of the first clamping portion, the first clamping portion comprises a first perforation, and the first contact portion passes through the first perforation and is partially disposed between the first clamping portion and the second clamping portion to contact the first electrode of the electrical component.

6. The electrical connecting device according to claim 5, wherein the first jig further comprises:
a first contact elastic sheet, disposed between the first clamping portion and the second clamping portion and fixed with the first clamping portion; and
a second contact elastic sheet, disposed opposite to the first contact elastic sheet, between the first clamping portion and the second clamping portion and fixed with the second clamping portion;
wherein the first clamping portion and the second clamping portion electrically connect and clamp the first electrode through the first contact elastic sheet and the second contact elastic sheet respectively.

7. The electrical connecting device according to claim 6, wherein in the first jig:
the first contact elastic sheet has a first through hole, and the first contact portion of the first detecting elastic sheet passes through the first through hole and is partially disposed between the first clamping portion and the second clamping portion so as to contact the first electrode of the electrical component.

8. The electrical connecting device according to claim 5, wherein the first jig comprises:
a first insulation sheet, clamped between the first clamping portion and the first detecting elastic sheet to insulate the first clamping portion from the first detecting elastic sheet.

9. The electrical connecting device according to claim 3, wherein in the second jig:
the first detecting elastic sheet is fixed to an outside part of the first clamping portion, the first clamping portion comprises a first perforation, and the first contact portion passes through the first perforation and is partially disposed between the first clamping portion and the second clamping portion so as to contact the second electrode of the electrical component; and
the second detecting elastic sheet is fixed to an outside part of the second clamping portion, the second clamping portion comprises a second perforation, and the second contact portion passes through the second perforation and is partially disposed between the first clamping portion and the second clamping portion so as to contact the second electrode of the electrical component.

10. The electrical connecting device according to claim 9, wherein the second jig further comprises:
a first contact elastic sheet, disposed between the first clamping portion and the second clamping portion and fixed with the first clamping portion; and
a second contact elastic sheet, disposed opposite to the first contact elastic sheet, between the first clamping portion and the second clamping portion and fixed with the second clamping portion;
wherein the first clamping portion and the second clamping portion electrically connect and clamp the second electrode through the first contact elastic sheet and the second contact elastic sheet respectively.

11. The electrical connecting device according to claim 10, wherein in the second jig:
the first contact elastic sheet has a first through hole, and the first contact portion of the first detecting elastic sheet passes through the first through hole and is partially disposed between the first clamping portion and the second clamping portion so as to contact the second electrode of the electrical component; and
the second contact elastic sheet has a second through hole, and the second contact portion of the second detecting elastic sheet passes through the second through hole and is partially disposed between the first clamping portion and the second clamping portion so as to contact the second electrode of the electrical component.

12. The electrical connecting device according to claim 9, wherein the second jig comprises:
a first insulation sheet, clamped between the first clamping portion and the first detecting elastic sheet to insulate the first clamping portion from the first detecting elastic sheet; and
a second insulation sheet, clamped between the second clamping portion and the second detecting elastic sheet to insulate the second clamping portion from the second detecting elastic sheet.

13. The electrical connecting device according to claim 3, further comprising:
a first relative sliding device, comprising a link, a fixed portion, a first sliding portion and a second sliding portion, wherein the first sliding portion of the first relative sliding device is fixed with the first clamping portion of the first jig, the second sliding portion of the first relative sliding device is fixed with the second clamping portion of the first jig, a first end of the link is pivotally fixed with the first sliding portion, a second end of the link is pivotally fixed with the second sliding portion, and a center of the link is pivotally fixed with the fixed portion;
a second relative sliding device, comprising a link, a fixed portion, a first sliding portion and a second sliding portion, wherein the first sliding portion of the second relative sliding device is fixed with the first clamping portion of the second jig, the second sliding portion of the second relative sliding device is fixed with the second clamping portion of the second jig, a first end of the link is pivotally fixed with the first sliding portion, a second end of the link is pivotally fixed with the second sliding portion, and a center of the link is pivotally fixed with the fixed portion; and
a connecting rod, fixed with the first sliding portion of the first relative sliding device and the first sliding portion of the second relative sliding device;
wherein when the connecting rod is pushed by an external force, the first clamping portion of the first jig and the second clamping portion of the first jig move in opposite directions and the first clamping portion of the second jig and the second clamping portion of the second jig move in opposite directions.

14. The electrical connecting device according to claim 13, wherein the electrical connecting device comprises a plurality of the first jigs and a plurality of the second jigs, the first jigs are used for electrically connecting and clamping the first electrodes of a plurality of the electrical components respectively, and the second jigs are used for electrically connecting and clamping the second electrodes of the plurality of the electrical components respectively, wherein:
the first sliding portion of the first relative sliding device is fixed with the first clamping portions of the first jigs, and the second sliding portion of the first relative sliding device is fixed with the second clamping portions of the first jigs; and
the first sliding portion of the second relative sliding device is fixed with the first clamping portions of the second jigs, and the second sliding portion of the second relative sliding device is fixed with the second clamping portions of the second jigs.

15. The electrical connecting device according to claim 13, further comprising a pneumatic cylinder fixed with the connecting rod to provide the external force.

16. The electrical connecting device according to claim 3, wherein the first sensor is a voltage sensor.

17. The electrical connecting device according to claim 3, wherein the second sensor is a temperature sensor.

18. The electrical connecting device according to claim 17, wherein the second sensor is a thermistor.

19. The electrical connecting device according to claim 3, wherein the first electrode of the electrical component is an anode, and the second electrode of the electrical component is a cathode.

20. The electrical connecting device according to claim 1, wherein the electrical component is a pouch-type battery.
